(19) United States
(12) Patent Application Publication
(10) Pub. No.: US 2025/0215869 A1
(43) Pub. Date: Jul. 3, 2025

(54) INVERTER-INTEGRATED ELECTRIC COMPRESSOR

(71) Applicant: SANDEN CORPORATION, Gunma (JP)

(72) Inventors: Toshimasa SHIMA, Gunma (JP); Taizo SATO, Gunma (JP)

(21) Appl. No.: 18/850,803

(22) PCT Filed: Mar. 21, 2023
(86) PCT No.: PCT/JP2023/011049

§ 371 Date: Sep. 25, 2024

(30) Foreign Application Priority Data
Apr. 22, 2022 (JP) 2022-070476

(51) Int. Cl. F04B 35/04; F04B 39/12; H02K 11/33; H05K 1/02

(52) U.S. Cl. CPC F04B 35/04; F04B 39/121; H02K 11/33; H05K 1/0203; H02K 2211/03; H05K 2201/066; H05K 2201/10015

(57) ABSTRACT

An inverter-integrated electric compressor that can suppress a rise in cost when a heat dissipation sheet is provided between a cover of an inverter accommodating portion and a circuit board. The inverter-integrated electric compressor includes a metal housing in which an electric motor is integrated; an inverter for driving the electric motor, an inverter accommodating portion that is formed in the housing and accommodates the inverter, and a metal cover that is fixed to the housing and blocks the inverter accommodating portion. The inverter includes a circuit board having a smoothing capacitor (a heating element), and the inverter-integrated electric motor includes a seat portion that is formed integrally with the cover at a position corresponding to the smoothing capacitor and protrudes toward the circuit board, and a first heat dissipation sheet placed between the seat portion and the circuit board.

### TECHNICAL FIELD

The present invention relates to an inverter-integrated electric compressor including an inverter accommodated in an inverter accommodating portion formed in a housing.

### BACKGROUND ART

In this type of inverter-integrated electric compressor, particularly an electric compressor configuring an air-conditioning system for a vehicle, an inverter is conventionally accommodated and fixed in an inverter accommodating portion (an inverter case) formed in a metal housing (an accommodating portion main body), and the inverter accommodating portion is furthermore blocked with a metal cover. Moreover, a smoothing capacitor that smooths power that is supplied to the inverter is molded with a resin case to be an assembly, and a heat dissipation sheet member is interposed between a circuit board of the assembly and the cover to enhance heat dissipation of the circuit board (refer to, for example, Patent Literature 1).

### CITATION LIST

### Patent Literature

Patent Literature 1: Japanese Patent No. 5697038

### SUMMARY OF INVENTION

### Problems to be Solved by Invention

Here, for example, two heat dissipation sheets placed on each other, or a thick heat dissipation sheet, is conventionally used to secure an insulation distance of a dimension in the thickness direction between the circuit board and the cover. However, since heat dissipation sheets are expensive, the use of two heat dissipation sheets or a thick heat dissipation sheet causes a rise in cost. Moreover, there are problems that thermal resistance increases due to an increase in the dimension in the thickness direction and that heat dissipation performance deteriorates.

The present invention has been made to solve such known technical problems, and an object thereof is to provide an inverter-integrated electric compressor that can suppress a rise in cost in a case where a heat dissipation sheet is provided between a cover of an inverter accommodating portion and a circuit board.

### Solution to Problems

An inverter-integrated electric compressor of the present invention includes: a metal housing in which a motor is integrated; an inverter for driving the motor; an inverter accommodating portion that is formed in the housing and accommodates the inverter; and a metal cover that blocks the inverter accommodating portion, in which the inverter includes a circuit board having a heating element, and the inverter-integrated electric compressor includes: a seat portion that is formed integrally with the cover at a position corresponding to the heating element and protrudes toward the circuit board; and a heat dissipation sheet placed between the seat portion and the circuit board.

In accordance with the invention of claim 2, in the inverter-integrated electric compressor according to the invention described above, the seat portion is located inward of an outer edge portion of the heat dissipation sheet.

In accordance with the invention of claim 3, in the inverter-integrated electric compressor according to the invention of claim 1, an outer surface of the cover is formed with a recessed portion corresponding in position to the seat portion.

In accordance with the invention of claim 4, the inverter-integrated electric compressor according to each of the inventions described above includes another heat dissipation sheet that is placed between a wall of the inverter accommodating portion at a position facing the cover and the circuit board and has the same thickness as the heat dissipation sheet placed between the seat portion and the circuit board.

### Effects of Invention

In accordance with the present invention, an inverter-integrated electric compressor including: a metal housing in which a motor is integrated; an inverter for driving the motor; an inverter accommodating portion that is formed in the housing and accommodates the inverter; and a metal cover that blocks the inverter accommodating portion is configured in such a manner that the inverter includes a circuit board having a heating element, and the inverter-integrated electric motor includes: a seat portion that is formed integrally with the cover at a position corresponding to the heating element and protrudes toward the circuit board; and a heat dissipation sheet placed between the seat portion and the circuit board. Therefore, it is possible to secure an insulation distance between the circuit board and the cover while reducing the number of the heat dissipation sheets or thinning the heat dissipation sheet.

Consequently, it is possible to enhance cost reduction, and to reduce the thermal resistance of the heat dissipation sheet itself. Therefore, the heat dissipation performance of the heating element mounted on the circuit board is also improved.

In particular, as in the invention of claim 2, it is configured in such a manner that the seat portion is located inward of the outer edge portion of the heat dissipation sheet. Therefore, it is possible to secure the insulation distance between the circuit board and the cover, that is, between the circuit board and the seat portion.

Moreover, as in the invention of claim 3, the outer surface of the cover is formed with the recessed portion corresponding in position to the seat portion. Therefore, it is also possible to improve the heat dissipation performance of the cover while avoiding an increase in the weight of the cover due to the formation of the seat portion.

Furthermore, as in the invention of claim 4, the another heat dissipation sheet having the same thickness as the heat dissipation sheet placed between the seat portion and the circuit board is placed between the wall of the inverter accommodating portion at the position facing the cover and the circuit board. Therefore, it is possible to sandwich the circuit board between the heat dissipation sheets having the same thickness and to receive a compressive load evenly on the circuit board.

Consequently, the necessity to mold the heating element in a resin case as in before is eliminated, and it is possible to enhance cost reduction and compactification of the inverter. Moreover, it is also possible to thin each of the heat dissipation sheets. Therefore, it is possible to improve heat dissipation performance by reducing thermal resistance and to enhance further cost reduction.

### BRIEF DESCRIPTION OF DRAWINGS

FIG. 1 is a schematic cross-sectional view of an inverter-integrated electric compressor according to an embodiment to which the present invention is applied.

FIG. 2 is a detailed vertical cross-sectional view of a portion around a filter capacitor of the electric compressor of FIG. 1.

FIG. 3 is an enlarged plan view of the portion around the filter capacitor excluding a cover of the electric compressor of FIG. 1.

FIG. 4 is a cross-sectional view taken along line A-A of FIG. 3.

### DESCRIPTION OF EMBODIMENTS

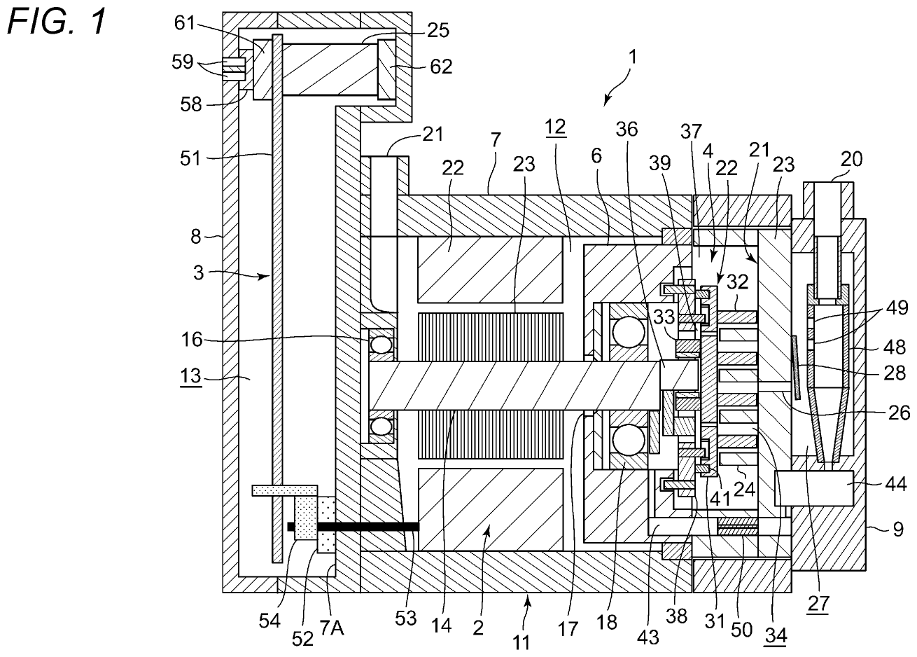

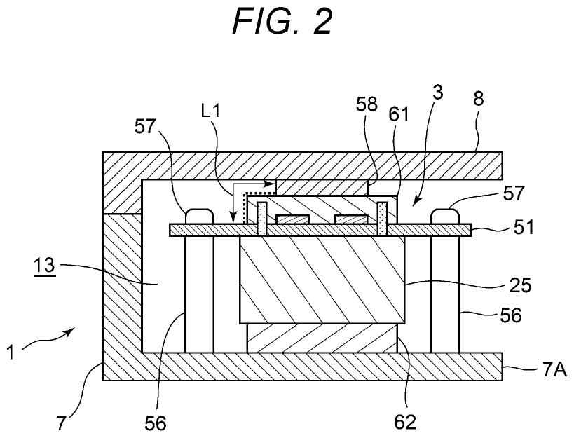

An embodiment of the present invention is described in detail hereinafter with reference to the drawings. FIG. 1 is a schematic cross-sectional view of an inverter-integrated electric compressor 1 according to an embodiment to which the present invention is applied. FIG. 2 is an enlarged vertical cross-sectional view of the electric compressor 1 in a portion around a smoothing capacitor 25 as a heating element in the present invention.

The inverter-integrated electric compressor 1 of an example is used, for example, in a refrigerant circuit of an air-conditioning system for a vehicle, and takes in and compresses a refrigerant as working fluid for the air-conditioning system, and discharges the refrigerant into a discharge pipe. The inverter-integrated electric compressor 1 is what is called a horizontal inverter-integrated scroll compressor including an electric motor 2 as a motor in the present invention, an inverter 3 for driving the electric motor 2, and a scroll compression mechanism 4 as a compression mechanism that is driven by the electric motor 2.

The electric compressor 1 of the example includes a stator housing 7 that accommodates the electric motor 2, the inverter 3, and a center casing 6, a cover 8, and a rear casing 9. The stator housing 7, the cover 8, and the rear casing 9 are all made of metal (aluminum in the example), and are integrally joined together to form a housing 11 of the electric compressor 1.

The stator housing 7 includes a partition 7A on one end side, and the partition 7A partitions the interior of the stator housing 7 (that forms a part of the housing 11) into a motor chamber 12 that accommodates the electric motor 2 and an inverter accommodating portion 13 that accommodates the inverter 3. One end surface of the inverter accommodating portion 13 is open. The inverter 3 is accommodated, and then the opening is blocked with the cover 8 that is fixed to the stator housing 7 (that forms the part of the housing 11). The other end surface of the motor chamber 12 is also open. The electric motor 2 is accommodated through the opening, and then the center casing 6 is accommodated through the opening. Moreover, a secondary bearing 16 for rotatably supporting one end portion (front side) of a drive shaft 14 of the electric motor 2 is attached on a motor chamber 12 side of the partition 7A.

The center casing 6 is open on an opposite side to the electric motor 2 (the other end side). After a moving scroll 22, which is described below, of the scroll compression mechanism 4 is accommodated, the rear casing 9 to which a fixed scroll 21, which is also described below, of the scroll compression mechanism 4 is fixed is fixed to the stator housing 7 to thereby block the opening.

Moreover, a through-hole 17 through which the other end portion of the drive shaft 14 of the electric motor 2 is inserted is opened in the center casing 6, and a main bearing 18 that rotatably supports the other end portion of the drive shaft 14 on a scroll compression mechanism 4 side of the through-hole 17 is attached on the scroll compression mechanism 4 side in the center casing 6.

The electric motor 2 includes a stator 22 around which a coil is wound and which is fixed to an inner side of a peripheral wall of the stator housing 7, and a rotor 23 that rotates inside the stator 22. In addition, it is configured in such a manner that, for example, direct current from a battery (not illustrated) of the vehicle is converted into three-phase alternating current by the inverter 3 to be supplied to the coil of the stator 22 of the electric motor 2, and therefore, the rotor 23 is rotationally driven. In addition, the drive shaft 14 is fixed to the rotor 23.

Moreover, an intake port 21 is formed in the stator housing 7, and the refrigerant taken in from the intake port 21 passes through the electric motor 2 in the stator housing 7, then flows into the center casing 6, and is taken into a suction portion 37 outside the scroll compression mechanism 4. Consequently, the electric motor 2 is cooled by the refrigerant that has been taken in. Moreover, it is configured in such a manner that the refrigerant compressed by the scroll compression mechanism 4 is discharged from a discharge chamber 27 described below into the discharge pipe of an unillustrated refrigerant circuit outside the housing 11 through a discharge port 20 formed in the rear casing 9.

The scroll compression mechanism 4 includes the above-mentioned fixed scroll 21 and moving scroll 22. The fixed scroll 21 integrally includes a disk-shaped end cover 23, and a wrap 24 erected on a surface (one surface) of the end cover 23, the wrap 24 having an involute shape or a spiral shape formed of a curve closer to the involute shape, and is fixed to the rear casing 9 with the surface, on which the wrap 24 is erected, of the end cover 23 facing the center casing 6. A discharge hole 26 is formed in the center of the end cover 23 of the fixed scroll 21, and the discharge hole 26 communicates with the discharge chamber 27 in the rear casing 9. In the drawing, a reference sign 28 denotes a discharge valve provided at an opening of the discharge hole 26 on a back (the other surface) side of the end cover 23.

The moving scroll 22 is a scroll that performs revolution motion relative to the fixed scroll 21, and integrally includes a disk-shaped end cover 31, a wrap 32 erected on a surface (one surface) of the end cover 31, the wrap 32 having an involute shape or a spiral shape formed of a curve closer to the involute shape, and a boss 33 protruding from the center of a back (the other surface) of the end cover 31. The moving scroll 22 is placed in such a manner that the wrap 32 faces and meshes with the wrap 24 of the fixed scroll 21 with the protruding direction of the wrap 32 facing the fixed scroll 21, and a pressure chamber 34 is formed between the wraps 24 and 32.

In other words, the wrap 32 of the moving scroll 22 faces the wrap 24 of the fixed scroll 21, and meshes with the wrap 24 of the fixed scroll 21 in such a manner that a distal end of the wrap 32 is in contact with the surface of the end cover 23 and a distal end of the wrap 24 is in contact with the surface of the end cover 31, and an eccentric portion 36 that is provided at the other end of the drive shaft 14 in such a manner as to be eccentric to the axis is fitted in the boss 33 of the moving scroll 22. In addition, it is configured in such a manner that when the drive shaft 14 is rotated together with the rotor 23 of the electric motor 2, then the moving scroll 22 performs revolution motion relative to the fixed scroll 21 without rotating on its axis.

Since the moving scroll 22 eccentrically revolves relative to the fixed scroll 21, the eccentric direction and contact position of the wraps 24 and 32 move during rotation, and the pressure chamber 34 that has taken the refrigerant in from the above-mentioned suction portion 37 on the outer side is gradually reduced while moving inward. Consequently, the refrigerant is compressed further and further, and finally discharged through the discharge hole 26 in the center into the discharge chamber 27 via the discharge valve 28.

In FIG. 1, a reference sign 38 denotes an annular thrust plate. The thrust plate 38 sections a back pressure chamber 39 formed between the back of the end cover 31 of the moving scroll 22 and the center casing 6, and the suction portion 37 outside the scroll compression mechanism 4, and is located outside the boss 33 and interposed between the center casing 6 and the moving scroll 22. Moreover, a reference sign 41 denotes a sealing member that is attached to the back of the end cover 31 of the moving scroll 22 and comes into contact with the thrust plate 38. The sealing member 41 and the thrust plate 38 section the back pressure chamber 39 and the suction portion 37.

Moreover, a reference sign 48 denotes a centrifugal oil separator attached in the discharge chamber 27 of the rear casing 9 (the housing 11). The oil separator 48 separates lubricating oil mixed in the refrigerant discharged from the scroll compression mechanism 4 into the discharge chamber 27, from the refrigerant. The oil separator 48 is formed with an entry opening 49, and the refrigerant containing the oil, which is flown through the entry opening 49, swirls in the oil separator 48. The oil is separated by a centrifugal force at this point in time, and the refrigerant flows from an exit opening at an upper end toward the discharge port 20 and is discharged into the discharge pipe as described above.

The rear casing 9 is formed with an oil reservoir chamber 44 below the oil separator 48, and the oil separated from the refrigerant by the oil separator 48 flows into the oil reservoir chamber 44 from a lower end of the oil separator 48. In the drawing, a reference sign 43 denotes a back pressure passage formed from the rear casing 9 to the center casing 6. The back pressure passage 43 is a path that causes the oil separator 48 in the discharge chamber 27 (a discharge side of the scroll compression mechanism 4) in the rear casing 9 to communicate with the back pressure chamber 39, and has an orifice 50 in the example. Consequently, it is configured in such a manner that discharge pressure adjusted and reduced by the orifice 50 of the back pressure passage 43, together with the oil in the oil reservoir chamber 44 separated by the oil separator 48, is supplied to the back pressure chamber 39.

Pressure (back pressure) in the back pressure chamber 39 generates a back pressure load that presses the moving scroll 22 against the fixed scroll 21. Under the back pressure load, the moving scroll 22 is pressed against the fixed scroll 21 against a compression reaction force from the pressure chamber 34 of the scroll compression mechanism 4, the contact between the wraps 24 and 32 and the end covers 31 and 23 is maintained, and the refrigerant can be compressed in the pressure chamber 34.

Next, a structure around the inverter 3 of the inverter-integrated electric compressor 1 of the example is described with further reference to FIGS. 2 to 4. In the inverter 3 of the example, a control circuit, a power switching element, and a smoothing capacitor (heating element) 25 are mounted on one circuit board 51. In this case, a glass hermetic plate 52 is attached on an inverter accommodating portion 13 side of the partition 7A at a position corresponding to one end side of the circuit board 51, and three conductive hermetic pins 53 are attached to the hermetic plate 52.

One end side of each of the hermetic pins 53 stands on the partition 7A in the inverter accommodating portion 13, and the other end side penetrates the partition 7A, enters the motor chamber 12, and is connected to the coil of the stator 22 of the electric motor 2. (Three) connection terminals 54 are each connected to one end side of the respective hermetic pin 53, and the hermetic pins 53 are each electrically connected to the circuit board 51 by the respective connection terminal 54.

The smoothing capacitor 25 as an example of the heating element in the present invention is attached by soldering to the other end side of the circuit board 51, and is accommodated in the inverter accommodating portion 13. The smoothing capacitor 25 forms a part of the circuit board 51, is a capacitive element that smooths power that is supplied to the inverter 3, and has a relatively heavy weight.

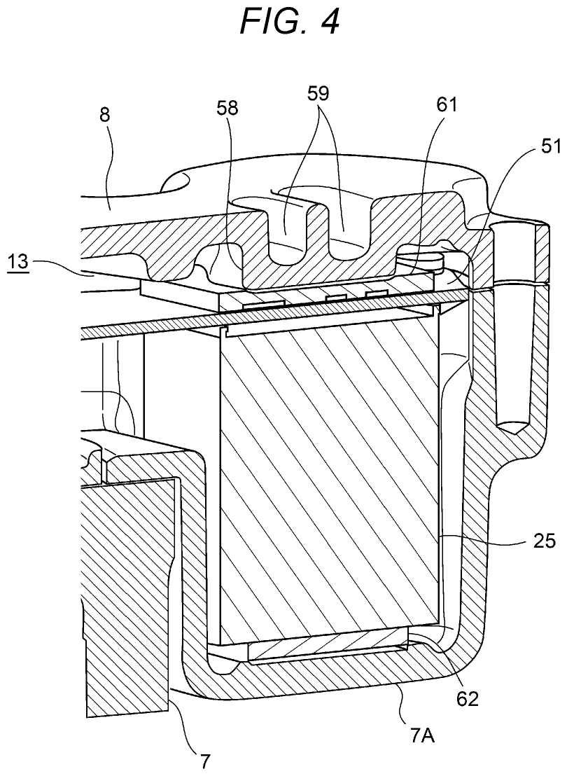

FIGS. 2 to 4 illustrate the structure of the portion around the smoothing capacitor 25 in an enlarged manner. In a case of the example, the circuit board 51 is fixed with a screw 57 to a column 56 standing on the partition 7A, and the smoothing capacitor 25 (the heating element) is located on a partition 7A side of the circuit board 51. In the present invention, the cover 8 at a position corresponding to the smoothing capacitor 25 is formed integrally with a seat portion 58 protruding toward the circuit board 51. Moreover, an outer surface of the cover 8 at a position corresponding to the seat portion 58 is formed with recessed portions 59 recessed as illustrated in FIG. 4 in two places in the example.

A first heat dissipation sheet 61 is placed between the seat portion 58 and the circuit board 51, and a second heat dissipation sheet 62 is provided between the smoothing capacitor 25 forming the part of the circuit board 51 and the partition 7A (a wall of the inverter accommodating portion 13 at a position facing the cover 8). Both of the heat dissipation sheets 61 and 62 are made of a silicone resin or a material such as gel, and have the same thickness.

Moreover, the first heat dissipation sheet 61 is in close contact with both of the circuit board 51 and the seat portion 58, and the second heat dissipation sheet 62 is in close contact with both of the partition 7A and the smoothing capacitor 25 (the circuit board 51). Consequently, it is configured in such a manner that the circuit board 51 including the smoothing capacitor 25 is sandwiched between the cover 8 and the partition 7A by both of the heat dissipation sheets 61 and 62, and heat generated by the smoothing capacitor 25 is transferred to the cover 8 and the partition 7A via the heat dissipation sheets 61 and 62, and dissipates.

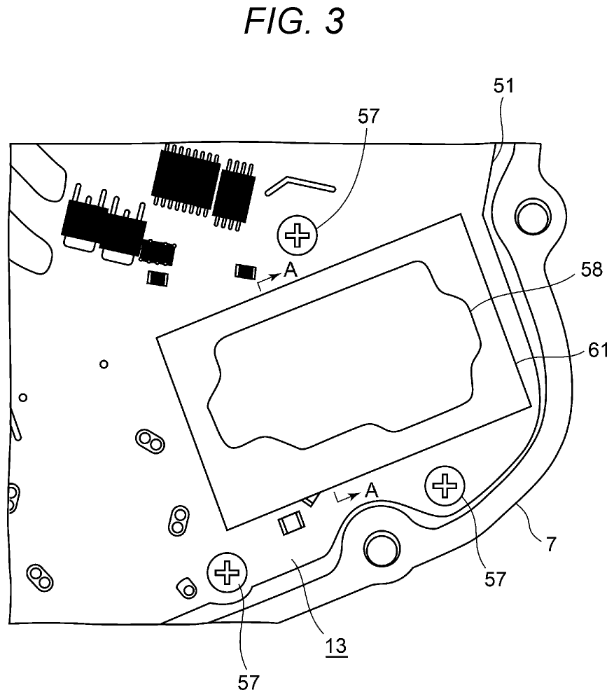

Moreover, as illustrated in FIG. 3, the seat portion 58 of the cover 8 is located inward of an outer edge portion of the first heat dissipation sheet 61 (in the drawing, the cover 8 is not illustrated, and only the seat portion 58 is illustrated.). Consequently, an insulation distance (creepage distance) indicated by L1 in FIG. 2 is secured between the circuit board 51 and the seat portion 58.

With the configuration described above, it is possible to secure the insulation distance between the circuit board 51 and the cover 8 while reducing the number of the heat dissipation sheets (the first heat dissipation sheets 61) or thinning the heat dissipation sheet as compared with before. Consequently, it is possible to enhance cost reduction, and it is possible to reduce the thermal resistance of the first heat dissipation sheet 61 itself. Therefore, the heat dissipation performance of the smoothing capacitor 25 (the heating element) mounted on the circuit board 51 is also improved.

In particular, as in the example, it is configured in such a manner that the seat portion 58 is located inward of the outer edge portion of the first heat dissipation sheet 61. Therefore, it is possible to secure the insulation distance (L1) between the circuit board 51 and the cover 8, that is, between the circuit board 51 and the seat portion 58.

Moreover, as in the example, the outer surface of the cover 8 is formed with the recessed portions 59 corresponding in position to the seat portion 58. Therefore, it is possible to increase the surface area of the cover 8 while avoiding an increase in the weight of the cover 8 due to the formation of the seat portion 58 and to improve heat dissipation performance.

Furthermore, as in the example, the second heat dissipation sheet 62 having the same thickness as the first heat dissipation sheet 61 placed between the seat portion 58 and the circuit board 51 is placed between the wall of the inverter accommodating portion 13 at the position facing the cover 8, that is, the partition 7A, and the circuit board 51, that is, the smoothing capacitor 25. Therefore, it is possible to sandwich the circuit board 51 (the smoothing capacitor 25) between the heat dissipation sheets 61 and 62 having the same thickness and to receive a compressive load evenly on the circuit board 51.

Consequently, the necessity to mold the smoothing capacitor 25 in a resin case as in before is eliminated, and it is possible to enhance cost reduction and compactification of the inverter 3. Moreover, it is also possible to thin each of the heat dissipation sheets 61 and 62. Therefore, it is possible to improve heat dissipation performance by reducing thermal resistance and to enhance further cost reduction.

Note that in the example, the smoothing capacitor 25 has been described as an example of the heating element. However, the heating element is not limited thereto. Various circuit elements that are mounted on the circuit board 51 and generate heat by energization are applicable as heating elements.

### LIST OF REFERENCE SIGNS

1 Inverter-integrated electric compressor
2 Electric motor (motor)
3 Inverter
4 Scroll compression mechanism (compression mechanism)
7 Stator housing
7A Partition
8 Cover
11 Housing
12 Motor chamber
13 Inverter accommodating portion
25 Smoothing capacitor (heating element)
51 Circuit board
58 Seat portion
59 Recessed portion
61 First heat dissipation sheet
62 Second heat dissipation sheet

1. An inverter-integrated electric compressor including: a metal housing in which a motor is integrated; an inverter for driving the motor; an inverter accommodating portion that is formed in the housing and accommodates the inverter; and a metal cover that blocks the inverter accommodating portion, wherein
the inverter includes a circuit board having a heating element, and
the inverter-integrated electric compressor comprises:
a seat portion that is formed integrally with the cover at a position corresponding to the heating element and protrudes toward the circuit board; and
a heat dissipation sheet placed between the seat portion and the circuit board.

2. The inverter-integrated electric compressor according to claim 1, wherein the seat portion is located inward of an outer edge portion of the heat dissipation sheet.

3. The inverter-integrated electric compressor according to claim 1, wherein an outer surface of the cover is formed with a recessed portion corresponding in position to the seat portion.

4. The inverter-integrated electric compressor according to claim 1, further comprising another heat dissipation sheet that is placed between a wall of the inverter accommodating portion at a position facing the cover and the circuit board and has the same thickness as the heat dissipation sheet placed between the seat portion and the circuit board.
